(19) United States
(12) Patent Application Publication
(10) Pub. No.: US 2025/0038563 A1
(43) Pub. Date: Jan. 30, 2025

(54) INDOOR CHARGER EQUIPMENT CROSS REFERENCE TO RELATED APPLICATIONS

(71) Applicants: INTERFACE TECHNOLOGY (CHENGDU) CO., LTD., SICHUAN (CN); INTERFACE OPTOELECTRONICS (SHENZHEN) CO., LTD, GUANGDONG (CN); GENERAL INTERFACE SOLUTION LIMITED, MIAOLI COUNTY (TW)

(72) Inventors: CHIA-CHEN YEH, GUANGDONG (CN); PO-LUN CHEN, GUANGDONG (CN)

(21) Appl. No.: 18/471,711

(22) Filed: Sep. 21, 2023

(30) Foreign Application Priority Data
Jul. 26, 2023 (CN) 2023109216496

(51) Int. Cl. H02J 7/35; H01L 31/032; H01L 31/043

(52) U.S. Cl. CPC H02J 7/35; H01L 31/032; H01L 31/043; H02J 2310/14

(57) ABSTRACT

An indoor charger equipment is applied to an indoor space with an artificial light source and an electric appliance. The indoor charger equipment includes a photoelectric conversion module and an electric energy storage device. The photoelectric conversion module includes a plurality of perovskite-based photovoltaic cells stacked into a multilayer structure. The multilayer structure is placed in the indoor space facing the artificial light source, so that the light sequentially penetrating these perovskite-based photovoltaic cells is absorbed and photoelectrically converted into electrical energy. The electric energy storage device is electrically connected with the photoelectric conversion module for storing the electric energy. The electric appliance is electrically connected with the electric energy storage device to receive the electric energy for operation. Therefore, the light energy that was wasted in places where silicon-based solar cells could not work can be effectively converted into electrical energy and recycled for reuse.

### CROSS REFERENCE TO RELATED APPLICATIONS

This application claims the priority benefits of China application serial No. 2023109216496, filed on Jul. 26, 2023. The entirety of each of the above-mentioned patent applications is hereby incorporated by reference herein and made a part of this specification.

### BACKGROUND OF THE INVENTION

### Field of the Invention

The present invention relates to a photovoltaic cell technology, particularly to an indoor charger equipment using a perovskite-based photovoltaic cell.

### Description of the Prior Art

Human being has worked hard to overcome the greenhouse effect for tens of years. Nowadays, green electricity is often required in the development process of human beings, and the problem of supplying green electricity needs solving urgently. It is the global goal to reduce carbon emissions by 45% in 2030. Thus, various environment protection technologies emerge, and the efficiencies thereof are persistently advancing. Most green electricity devices, such as the silicon-based solar cells, are placed outdoors. Generally, indoor artificial light sources have very low illuminance and very narrow frequency bands, only functioning to illuminate and decorate. Because the indoor artificial light sources have a very low density of energy, the silicon-based solar cells cannot operate indoors but can only perform photoelectric conversion under sunlight illumination. However, solar power is likely to be affected by weather, light exposure, and dusts, thus instable in power generation efficiency. Besides, the industry still lacks a potential indoor green electricity device currently.

Accordingly, the present invention proposes an indoor charger equipment, which can use indoor artificial light sources to generate electricity and charge batteries, whereby to effectively solve the abovementioned problems.

### SUMMARY OF THE INVENTION

The primary objective of the present invention is to provide an indoor charger equipment, which makes use of the characteristics of perovskite-based photovoltaic cells to effectively convert the light energy, which the silicon-based solar cells cannot utilize, into electric energy and recycle the light energy, which is originally wasted.

In order to achieve the abovementioned objective, the present invention provides an indoor charger equipment, which is used in an indoor space having an artificial light source and an electric appliance, and which comprises a photoelectric conversion module and an electric energy storage device. The artificial light source emits light. The photoelectric conversion module includes a plurality of perovskite-based photovoltaic cells. The perovskite-based photovoltaic cells are stacked into a multilayer structure facing the artificial light source and placed in the indoor space. The perovskite-based photovoltaic cells receive light. The light penetrates the perovskite-based photovoltaic cells in sequence, absorbed and converted into electric energy by the perovskite-based photovoltaic cells. The electric energy storage device is electrically connected with the photoelectric conversion module and electric appliance to store electric energy and output electric energy to the electric appliance for operation.

In one embodiment of the present invention, the abovementioned perovskite-based photovoltaic cell is a penetration-type perovskite-based photovoltaic cell.

In one embodiment of the present invention, the abovementioned photoelectric conversion module includes a transparent insulating layer at least formed between the perovskite-based photovoltaic cells.

In one embodiment of the present invention, the abovementioned transparent insulating layer also cover the outer sides of the perovskite-based photovoltaic cells.

In one embodiment of the present invention, the areas of the perovskite-based photovoltaic cells gradually increase from the side near the artificial light source to the side far away from the artificial light source.

In one embodiment of the present invention, the perovskite-based photovoltaic cell far away from the artificial light source has the lowest light transmittance.

In one embodiment of the present invention, the perovskite-based photovoltaic cells have openings allowing light to pass except the perovskite-based photovoltaic cell far away from the artificial light source.

In one embodiment of the present invention, the photoelectric conversion module has three or more perovskite-based photovoltaic cells and two or more openings. The sizes of the openings gradually increase from the side near the artificial light source to the side far away from the artificial light source.

In one embodiment of the present invention, the photoelectric conversion module has three or more perovskite-based photovoltaic cells and two or more openings. The sizes of the openings gradually decrease from the side near the artificial light source to the side far away from the artificial light source.

In one embodiment of the present invention, each of the perovskite-based photovoltaic cells has an insulating layer on a side thereof, which is far away from the artificial light source.

In one embodiment of the present invention, except the perovskite-based photovoltaic cell far away from the artificial light source, each of the perovskite-based photovoltaic cells has a reflecting layer on a side thereof, which is far away from the artificial light sources, and the reflecting layer is separated from the perovskite-based photovoltaic cell by an insulating layer.

In one embodiment of the present invention, except the perovskite-based photovoltaic cell far away from the artificial light source, each of the perovskite-based photovoltaic cells has an insulating layer on a side thereof, which is far away from the artificial light source, and the perovskite-based photovoltaic cell is separated from an additional perovskite-based photovoltaic cell by the insulating layer.

In one embodiment of the present invention, the photoelectric conversion module is disposed on the inner surface of a lampshade.

In one embodiment of the present invention, the indoor charger equipment has a plurality of photoelectric conversion modules arranged on a surface without overlapping.

In comparison with the prior arts, the indoor charger equipment of the present invention has the efficacies: operating in the place where the conventional silicon-based photovoltaic cells cannot operate, recycling the light energy originally wasted by the conventional silicon-based photovoltaic cells, and effectively converting the light energy into electric energy. In recent years, the efficiency of the perovskite-based photovoltaic cells has greatly risen or even exceeded the efficiency of the silicon-based photovoltaic cells. Further, the perovskite-based photovoltaic cell has advantages of simple fabrication process, low cost, and flexibility.

Below, the embodiments of the present invention will be described in detail to make easily understood the objectives, technical contents, characteristics, and accomplishments of the present invention.

### BRIEF DESCRIPTION OF THE DRAWINGS

FIG. 1 is a block diagram schematically showing an indoor charger equipment according to one embodiment of the present invention.

FIG. 2 is a diagram schematically showing the configuration of an indoor charger equipment according to one embodiment of the present invention.

FIG. 3 is a diagram schematically showing a stack structure of the photoelectric conversion module according to a first embodiment of the present invention.

FIG. 4 is a diagram schematically showing a stack structure of the photoelectric conversion module according to a second embodiment of the present invention.

FIG. 5 is a diagram schematically showing a stack structure of the photoelectric conversion module according to a third embodiment of the present invention.

FIG. 6 is a diagram schematically showing a stack structure of the photoelectric conversion module according to a fourth embodiment of the present invention.

FIG. 7 is a diagram schematically showing that an indoor charger equipment is applied to floor titles and wall titles according to a fifth embodiment of the present invention.

FIG. 8 is a sectional view schematically showing the photoelectric conversion module is disposed on a planar surface of a lampshade according to a sixth embodiment of the present invention.

FIG. 9 is a sectional view schematically showing the photoelectric conversion module is disposed on a curved surface of a lampshade according to a seventh embodiment of the present invention.

### DETAILED DESCRIPTION OF THE INVENTION

Thereinafter, the present invention will be described in detail with the embodiments to enable the person having ordinary knowledge of the art to further understand the present invention.

The embodiments of the present invention are only to exemplify the present invention but not to limit the scope of the present invention. It should be particularly mentioned: while the ordinals, such as “first”, “second”, “third”, and “fourth”, are used to describe common objects, it is only to mean that these objects are different individual existences of similar objects but not to indicate that these objects should be arranged in a specified order or in a specified sequence unless there is a particular explanation in the text. In the condition that no conflict exists, the embodiments and the characteristics of the embodiments can be recombined arbitrarily. The scientific terms and technological terms used in the present invention have the same meanings as the persons having ordinary knowledge in the field understand unless they are particularly explained.

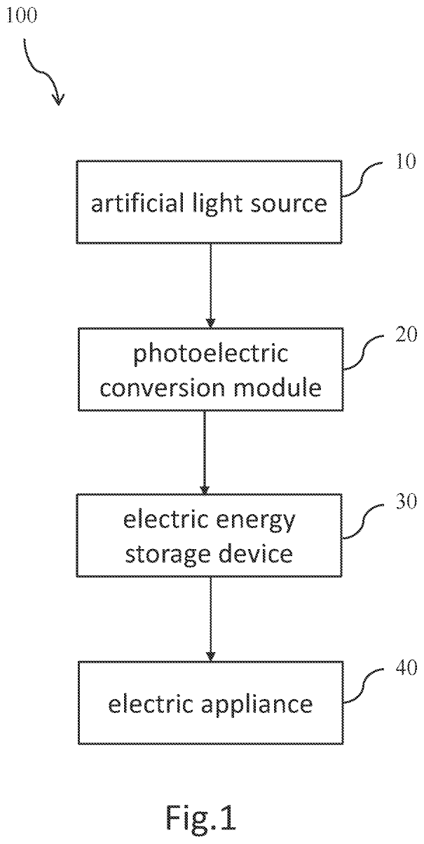

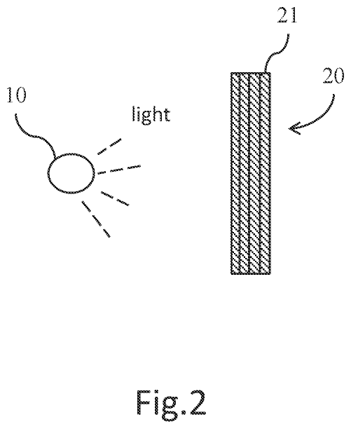

Refer to FIG. 1 and FIG. 2. FIG. 1 is a block diagram schematically showing an indoor charger equipment according to one embodiment of the present invention. FIG. 2 is a diagram schematically showing the configuration of an indoor charger equipment according to one embodiment of the present invention. The indoor charger equipment 100 of the present invention is used in an indoor space having an artificial light source 10 and an electric appliance 40. The indoor charger equipment 100 comprises a photoelectric conversion module 20 and an electric energy storage device 30.

The artificial light source 10 is a light source disposed in an indoor space, emitting light for illumination or decoration. The artificial light source 10 may be but is not limited to be an incandescent bulb, a halogen bulb, a mercury lamp, a fluorescent lamp, or a LED lamp.

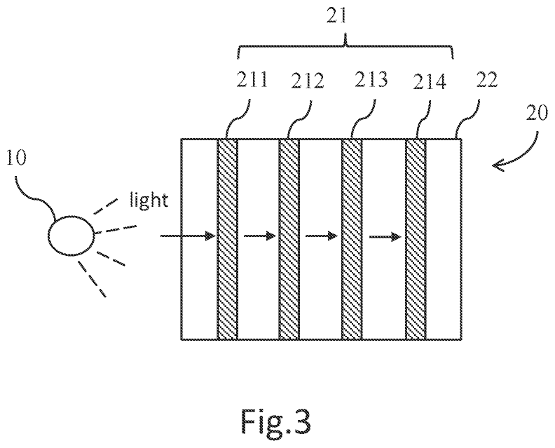

The photoelectric conversion module 20 includes a plurality of perovskite-based photovoltaic cells 21. The perovskite-based photovoltaic cell 21 is made of a perovskite-structured ceramic material, which may be expressed by a general chemical formula ABX₃, wherein A is a monovalent cation; B is a divalent cation; X is a monovalent halogen anion. It is preferred: the perovskite-based photovoltaic cell 21 used by the present invention is a penetration-type perovskite-based photovoltaic cell having the characteristics of a thin-film battery: light penetrability and flexibility. The perovskite-based photovoltaic cells 21 are stacked to form a multilayer structure, as shown in FIGS. 3-6 which respectively schematically show several embodiments of the multilayer structures of the perovskite-based photovoltaic cells 21. The multilayer structures of the perovskite-based photovoltaic cells 21 will be further demonstrated in detail thereinafter. The multilayer structure is disposed in the indoor space and faced to the artificial light source 10 to receive the light emitted by the artificial light source 10. After penetrating the perovskite-based photovoltaic cells 21 in sequence, the perovskite-based photovoltaic cells 21 absorb the light, convert the light into electric energy, and then output the electric energy to the electric energy storage device 30.

The electric energy storage device 30 is electrically connected with the photoelectric conversion module 20, receives and stores the electric energy output by the photoelectric conversion module 20, and provides the electric energy to the electric appliance 40. The electric energy storage device 30 may be but is not limited to be a battery, a reserve-type electric water heater, or a heat-storage electric heater.

The electric appliance 40 is electrically connected with the electric energy storage device 30, receiving the electric energy stored by the electric energy storage device 30 for operation. The electric appliance 40 may be but is not limited to be a light-current electric appliance, such as a telephone, a computer, a television, an audio device, or a broadcasting system, an air conditioner, an electric water heater, or an electric radiator.

Next, the photoelectric conversion module 20 containing four perovskite-based photovoltaic cells 21 is used to illustrate several stack structures of the perovskite-based photovoltaic cells 21. In the following several embodiments, four perovskite-based photovoltaic cells 21 are respectively named as a first perovskite-based photovoltaic cell 211, a second perovskite-based photovoltaic cell 212, a third perovskite-based photovoltaic cell 213, and a fourth perovskite-based photovoltaic cell 214 from the side close to the artificial light source 10 to the side far away from the artificial light source 10.

Refer to FIG. 3, which schematically shows a stack structure of the photoelectric conversion module according to a first embodiment of the present invention. In the first embodiment, a transparent insulating layer 22 is formed between the perovskite-based photovoltaic cells 21 of the photoelectric conversion module 20. The transparent insulating layer 22 is made of a transparent insulating material, such as an epoxy resin. The transparent insulating layer 22 fully covers the outer side of the perovskite-based photovoltaic cell 21. In the first embodiment, all of the first perovskite-based photovoltaic cell 211, the second perovskite-based photovoltaic cell 212, the third perovskite-based photovoltaic cell 213, and the fourth perovskite-based photovoltaic cell 214 have the same area. Suppose that each of the perovskite-based photovoltaic cells 21 has the same photoelectric conversion efficiency, such as a photoelectric conversion efficiency of 25%, and suppose that each of the perovskite-based photovoltaic cells 21 has the same light transmittance, such as a light transmittance of 50%. While the light passes through the first perovskite-based photovoltaic cell 211, the second perovskite-based photovoltaic cell 212, the third perovskite-based photovoltaic cell 213, and the fourth perovskite-based photovoltaic cell 214 in sequence, the photoelectric conversion process is shown in Table.1. It is learned from Table.1: in comparison with a single layer of the perovskite-based photovoltaic cell 21 having a photoelectric conversion efficiency of 25%, the stack structure of the four layers of the perovskite-based photovoltaic cells 21 has a photoelectric conversion efficiency of 46.875%. In other words, the stack structure of the first embodiment can increase the photoelectric conversion efficiency by 21.875%.

TABLE 1

| | Received light | Recycled electric |
|---|---|---|
| | energy | energy |
| First perovskite-based | 100% | 25% |
| photovoltaic cell | | |
| Second perovskite-based | 50% | 12.5% |
| photovoltaic cell | | |
| Third perovskite-based | 25% | 6.25% |
| photovoltaic cell | | |
| Fourth perovskite-based | 12.5% | 3.125% |
| photovoltaic cell | | |

In the first embodiment, all the perovskite-based photovoltaic cells 21 have the same light transmittance. However, the perovskite-based photovoltaic cells 21 may respectively have different light transmittances in practice. Further, the light transmittance of the perovskite-based photovoltaic cell 21 far away from the artificial light source 10, i.e. the fourth perovskite-based photovoltaic cell 214, may be reduced via modifying the material, whereby to increase the photoelectric conversion efficiency. In the first embodiment, all the perovskite-based photovoltaic cells 21 have the same area. However, the perovskite-based photovoltaic cells 21 may respectively have different areas in practice. Further, the area of the perovskite-based photovoltaic cell 21 may gradually increase from the side near the artificial light source 10 to the side far away from the artificial light source 10. In other words, the areas of the fourth perovskite-based photovoltaic cell 214, the third perovskite-based photovoltaic cell 213, the second perovskite-based photovoltaic cell 212, and the first perovskite-based photovoltaic cell 211 decrease in sequence.

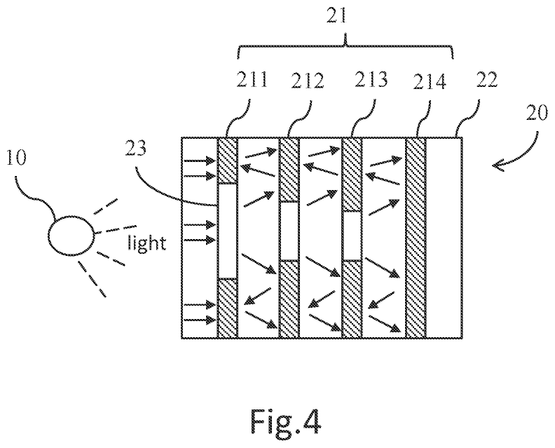

Refer to FIG. 4, which schematically shows a stack structure of the photoelectric conversion module according to a second embodiment of the present invention. The second embodiment is different from the first embodiment in the aspect: except the perovskite-based photovoltaic cell 21 far away from the artificial light source 10 (i.e. the fourth perovskite-based photovoltaic cell 214), the rest of the perovskite-based photovoltaic cells 21 (i.e. the first perovskite-based photovoltaic cell 211, the second perovskite-based photovoltaic cell 212, and the third perovskite-based photovoltaic cell 213) all have openings 23 at the central regions thereof. The light will pass all the openings 23 and finally reach the fourth perovskite-based photovoltaic cell 214. The openings 23 are to prevent some of the frequency bands of the light from being filtered out by the perovskite-based photovoltaic cells 21 and increase the utilization efficiency of the frequency bands of the light.

While the photoelectric conversion module 20 has three or more perovskite-based photovoltaic cells 21, the total number of the openings 23 is two or more. The openings 23 gradually grow larger from the side near the artificial light source 10 to the side far away from the artificial light source 10. In another embodiment, the openings 23 may gradually grow smaller from the side near the artificial light source 10 to the side far away from the artificial light source 10. In the second embodiment, the photoelectric conversion module 20 includes four perovskite-based photovoltaic cells 21; the openings 23 decrease in sizes in the sequence of the first perovskite-based photovoltaic cell 211, the second perovskite-based photovoltaic cell 212, and the third perovskite-based photovoltaic cell 213 except the fourth perovskite-based photovoltaic cell 214, whereby more light of the full frequency bands can reach the fourth perovskite-based photovoltaic cell 214.

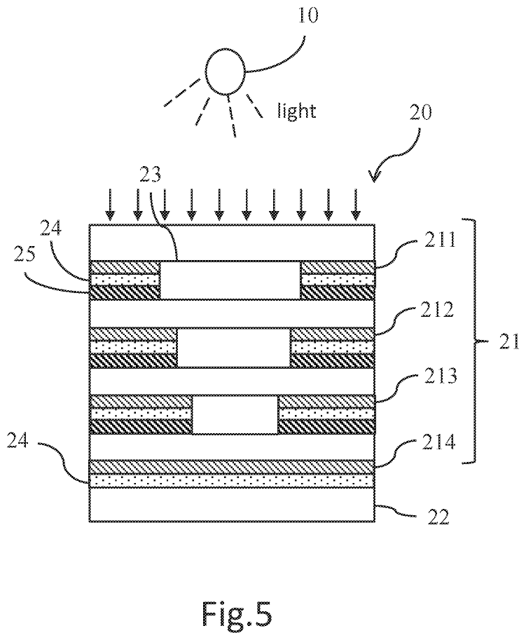

Refer to FIG. 5, which schematically shows a stack structure of the photoelectric conversion module according to a third embodiment of the present invention. The third embodiment is different from the second embodiment in the aspect: one side of each perovskite-based photovoltaic cell 21, which is far away from the artificial light source 10, has an insulating layer 24; and the aspect: except the perovskite-based photovoltaic cell 21 far away from the artificial light source 10 (i.e. the fourth perovskite-based photovoltaic cell 214), one side of each of the first perovskite-based photovoltaic cell 211, the second perovskite-based photovoltaic cell 212, and the third perovskite-based photovoltaic cell 213, which is far away from the artificial light source 10, has a reflecting layer 25. Besides, each perovskite-based photovoltaic cell 21 is separated from the reflecting layer 25 by the insulating layer 24. In the third embodiment, the reflecting layer 25 is made of a high-reflectivity material, whereby there will be more cycles of light reflections between the perovskite-based photovoltaic cells 21 and more cycles of light entrances into the perovskite-based photovoltaic cells 21.

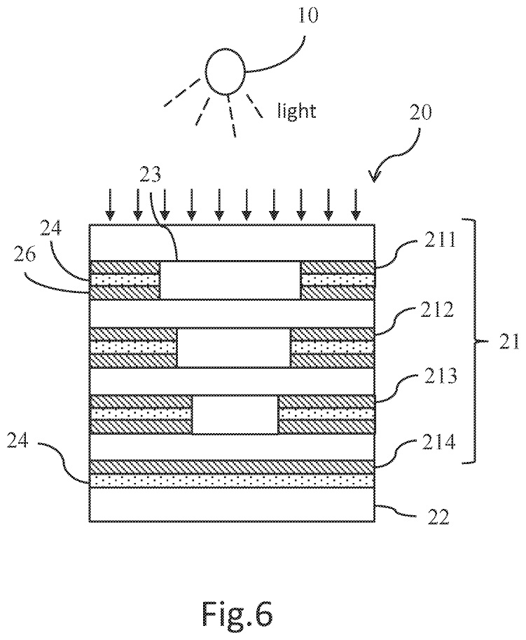

Refer to FIG. 6, which schematically shows a stack structure of the photoelectric conversion module according to a fourth embodiment of the present invention. The fourth embodiment is different from the third embodiment in the aspect: one side of each perovskite-based photovoltaic cell 21, which is far away from the artificial light source 10, i.e. the back side of the perovskite-based photovoltaic cell 21, has an insulating layer 24, and the aspect: except the perovskite-based photovoltaic cell 21 far away from the artificial light source 10 (i.e. the fourth perovskite-based photovoltaic cell 214), one side of each of the first perovskite-based photovoltaic cell 211, the second perovskite-based photovoltaic cell 212, and the third perovskite-based photovoltaic cell 213, which is far away from the artificial light source 10, has a perovskite-based photovoltaic cell 26. Besides, each perovskite-based photovoltaic cell 21 is separated from the perovskite-based photovoltaic cell 26 by the insulating layer 24. In the fourth embodiment, the additional perovskite-based photovoltaic cells 26 may increase the probability that the light enters the perovskite-based photovoltaic cells 21 and 26.

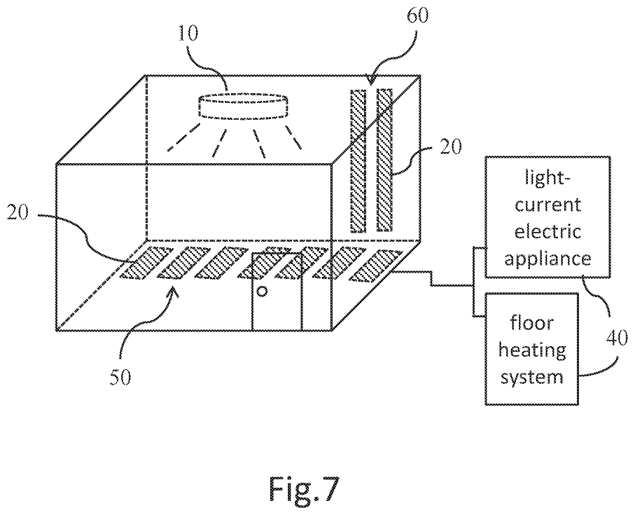

The indoor charger equipment of the present invention may be applied to household indoor spaces. Refer to FIG. 7, which schematically shows that an indoor charger equipment is applied to floor titles and wall titles according to a fifth embodiment of the present invention, wherein the electric energy storage device is not depicted. In the fifth embodiment, a plurality of photoelectric conversion modules 20 is used. The plurality of photoelectric conversion module 20 is arranged planarly inside floor titles 50 or wall titles 60. While the indoor illumination device (i.e. the artificial light source 10) is turned on, the photoelectric conversion modules 20 inside the floor titles 50 and the wall titles 60 simultaneously generate power to the electric appliances 40, such as light-current electric appliances, electric water heaters, and floor heating systems.

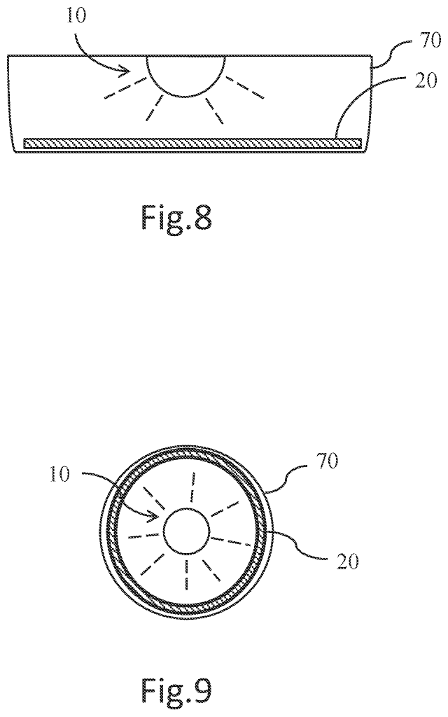

In order to achieve industrial power saving, the lampshade of the photolithographic illumination device is covered by the photoelectric conversion module, whereby to achieve illumination and power generation simultaneously. In addition to recycle electric energy and reduce carbon emission, the present invention can absorb the short-wavelength light source (the wavelengths thereof are shorter than 500 nm), which the photolithographic process should keep away from. Refer to FIG. 8 for a sixth embodiment of the present invention, wherein the photoelectric conversion module 20 is disposed on a planar surface of a lampshade 70. FIG. 9 for a seventh embodiment of the present invention, wherein the photoelectric conversion module 20, favored by the flexibility of the perovskite-based photovoltaic cell, is disposed on a curved surface of a lampshade 70.

Below is discussed the efficacy of the present invention applied to an environment using 200 pieces of tube lamps. A LED tube lamp consumes a power of 0.025 KWh/hr. Suppose that the photoelectric conversion efficiency of a perovskite-based photovoltaic cell is 20% (i.e. able to recycle 20% electric energy). If the stack structure of the first embodiment is adopted, each photoelectric conversion module has four perovskite-based photovoltaic cells and has a photoelectric conversion efficiency of 46.875%. Thus, 0.025 (KWh/hr)×0.46875 (conversion efficiency)×200 (pieces of tube lamps)×24 (hr)×365 (days)=20531.25 KWh/yr, i.e. 20.5 MWh/yr. 20.5 MWh/yr×0.554 (kg/KWh)=11.357 ton/yr. It means that 11.357 tons of CO₂ emissions will be reduced each year. Via applying to the illumination of a photolithographic environment, the present invention can recycle electric energy, reduce CO₂ emissions, raise the ratio of green electricity, and push up carbon neutralization.

In conclusion, the present invention provides an indoor charger equipment, which has a multilayer structure of perovskite-based photovoltaic cells able to absorb short-wavelength light. The perovskite-based photovoltaic cells of the indoor charger equipment of the present invention can convert the light energy, which is not utilized but wasted by the conventional silicon-based photovoltaic cells, into electric energy. Further, the efficiency of the perovskite-based photovoltaic cells used by the present invention has greatly advanced or even exceeded the efficiency of the conventional silicon-based photovoltaic cells in recent years. Furthermore, the perovskite-based photovoltaic cell has the advantages of simply fabrication process, low cost, and flexibility. Besides, the indoor charger equipment can be efficiently applied to the existing indoor furniture without occupying space.

The embodiments described above are only to exemplify the present invention but not to limit the scope of the present invention. Any equivalent modification or variation according to the spirit or characteristics of the present invention is to be also included by the scope of the present invention.

What is claimed is:

1. An indoor charger equipment, applied to an indoor space that has an artificial light source emitting light and an electric appliance, the indoor charger equipment comprising:
a photoelectric conversion module, including a plurality of perovskite-based photovoltaic cells, wherein the plurality of perovskite-based photovoltaic cells is stacked to form a multilayer structure; the multilayer structure is disposed in the indoor space and faced to the artificial light source to receive the light; after the light penetrates the plurality of perovskite-based photovoltaic cells in sequence, the light is received by the plurality of perovskite-based photovoltaic cells and converted into electric energy by the plurality of perovskite-based photovoltaic cells; and
an electric energy storage device, electrically connected with the photoelectric conversion module and the electric appliance, storing the electric energy, and outputting the electric energy to the electric appliance for operation.

2. The indoor charger equipment according to claim 1, wherein the perovskite-based photovoltaic cells are penetration-type perovskite-based photovoltaic cells.

3. The indoor charger equipment according to claim 1, wherein the photoelectric conversion module further includes a transparent insulating layer; the transparent insulating layer is at least disposed between the perovskite-based photovoltaic cells.

4. The indoor charger equipment according to claim 3, wherein the transparent insulating layer also covers outer sides of the perovskite-based photovoltaic cells.

5. The indoor charger equipment according to claim 1, wherein areas of the perovskite-based photovoltaic cells gradually increase from a side near the artificial light source to a side far away from the artificial light source.

6. The indoor charger equipment according to claim 1, wherein the perovskite-based photovoltaic cell far away from the artificial light source has a lowest light transmittance.

7. The indoor charger equipment according to claim 1, wherein except the perovskite-based photovoltaic cell far away from the artificial light source, others of the perovskite-based photovoltaic cells respectively have openings allowing the light to pass.

8. The indoor charger equipment according to claim 7, wherein the photoelectric conversion module includes three or more perovskite-based photovoltaic cells, and the perovskite-based photovoltaic cells have two or more openings; sizes of the two or more openings gradually increase from a side near the artificial light source to a side far away from the artificial light source.

9. The indoor charger equipment according to claim 7, wherein the photoelectric conversion module includes three or more perovskite-based photovoltaic cells, and the perovskite-based photovoltaic cells have two or more openings; sizes of the two or more openings gradually decrease from a side near the artificial light source to a side far away from the artificial light source.

10. The indoor charger equipment according to claim 1, wherein each of the perovskite-based photovoltaic cells has an insulating layer on a side thereof, which is far away from the artificial light source.

11. The indoor charger equipment according to claim 10, wherein except the perovskite-based photovoltaic cell far away from the artificial light source, each of the perovskite-based photovoltaic cells has a reflecting layer, wherein the reflecting layer is on a side of the perovskite-based photovoltaic cell, which is far away from the artificial light source, and wherein the reflecting layer is separated from the perovskite-based photovoltaic cell by the insulating layer.

12. The indoor charger equipment according to claim 10, wherein except the perovskite-based photovoltaic cell far away from the artificial light source, each of the perovskite-based photovoltaic cells has an additional perovskite-based photovoltaic cell, and wherein the additional perovskite-based photovoltaic cell is on a side of the perovskite-based photovoltaic cell, which is far away from the artificial light source, and wherein the additional perovskite-based photovoltaic cell is separated from the perovskite-based photovoltaic cell by the insulating layer.

13. The indoor charger equipment according to claim 1, wherein the photoelectric conversion module is disposed on an inner surface of a lampshade.

14. The indoor charger equipment according to claim 1, comprising a plurality of photoelectric conversion modules arranged planarly.
